(19) United States
(12) Patent Application Publication
(10) Pub. No.: US 2014/0055405 A1
(43) Pub. Date: Feb. 27, 2014

(54) TOUCH ELECTRODE DEVICE AND A METHOD OF MANUFACTURING THE SAME

(71) Applicant: HENGHAO TECHNOLOGY CO. LTD, Taoyuan County (TW)

(72) Inventor: KUAN-YEN MA, Taoyuan County (TW)

(73) Assignee: HengHao Technology Co. LTD, Taoyuan County (TW)

(21) Appl. No.: 13/677,135

(22) Filed: Nov. 14, 2012

(30) Foreign Application Priority Data
Aug. 23, 2012 (TW) 101130725

(51) Int. Cl. G06F 3/044; H05K 3/10

(52) U.S. Cl. CPC G06F 3/044; H05K 3/10
USPC 345/174; 427/97.4; 427/555

(57) ABSTRACT

A touch electrode device includes plural insulation bases disposed on a substrate, each insulation base having an undercut profile such that its top area is greater than its bottom area; plural first electrode lines disposed on the insulation bases respectively; and plural second electrode lines disposed on the substrate.

### CROSS-REFERENCE TO RELATED APPLICATIONS

This application claims priority to Taiwan Patent Application No. 101130725, filed on Aug. 23, 2012, the entire contents of which are hereby incorporated by reference.

### BACKGROUND OF THE INVENTION

1. Field of the Invention

The present invention generally relates to a touch electrode device, and more particularly to a touch electrode device without trace.

2. Description of Related Art

A touch screen is an input/output device that adopts sensing technology and display technology, and has been widely employed in electronic devices such as portable or hand-held electronic devices.

A capacitor-based touch panel is a commonly used touch panel that utilizes capacitive coupling effect to detect touch position. Specifically, capacitance corresponding to the touch position changes and is thus detected, when a finger touches a surface of the touch panel.

FIG. 1 shows a top view of a conventional touch panel, in which vertical electrode lines 11 and horizontal electrode lines 12 are formed on the same surface of a glass plate, where the vertical electrode lines 11 and the horizontal electrode lines 12 are electrically insulated from each other by insulation bridges 13. The vertical electrode lines 11 and the horizontal electrode lines 12 of the conventional touch panel as shown in FIG. 1 should be formed in respective steps, and gap need be reserved for preventing electrically shoring between the vertical electrode lines 11 and the horizontal electrode lines 12. Accordingly, trace phenomenon occurs when users look at the touch panel.

For the reason that the conventional touch panel requires complex manufacturing process and possesses visual trace, a need has arisen to propose a novel touch electrode device and an associated manufacturing method to overcome disadvantages of the conventional touch panel.

### SUMMARY OF THE INVENTION

In view of the foregoing, it is an object of the embodiment of the present invention to provide a touch electrode device and an associated manufacturing method that adopts a single step for forming touch electrodes overall. As no gap exists between electrodes, the manufactured touch electrode device possesses no visual trace when users look at the touch electrode device.

According to one embodiment, a touch electrode device includes a substrate, plural insulation bases, plural first electrode lines and plural second electrode lines. Specifically, the insulation bases are disposed on the substrate, and each insulation base has an undercut profile such that a top area of the insulation base is greater than a bottom area of the insulation base. The first electrode lines are disposed on the insulation bases respectively, and the second electrode lines are disposed on the substrate. In one embodiment, an insulation layer is formed on a substrate, which is then subjected to patterning with a pattern of the first electrode lines to form the insulation bases. Subsequently, an electrode layer is formed on the substrate and the insulation bases, thereby resulting in the first electrode lines disposed on the insulation bases and the second electrode lines disposed on the substrate.

### BRIEF DESCRIPTION OF THE DRAWINGS

FIG. 1 shows a top view of a conventional touch panel;

FIG. 2A and FIG. 2B show top views of a touch electrode device according to embodiments of the present invention;

FIG. 3A to FIG. 3D show cross-sectional views illustrating a method of manufacturing the touch electrode device 2 of FIG. 2A/B;

FIG. 4 shows a cross-sectional view along a section line 4-4′ in FIG. 2A; and

FIG. 5 shows a cross-sectional view along a section line 5-5′ in FIG. 2B.

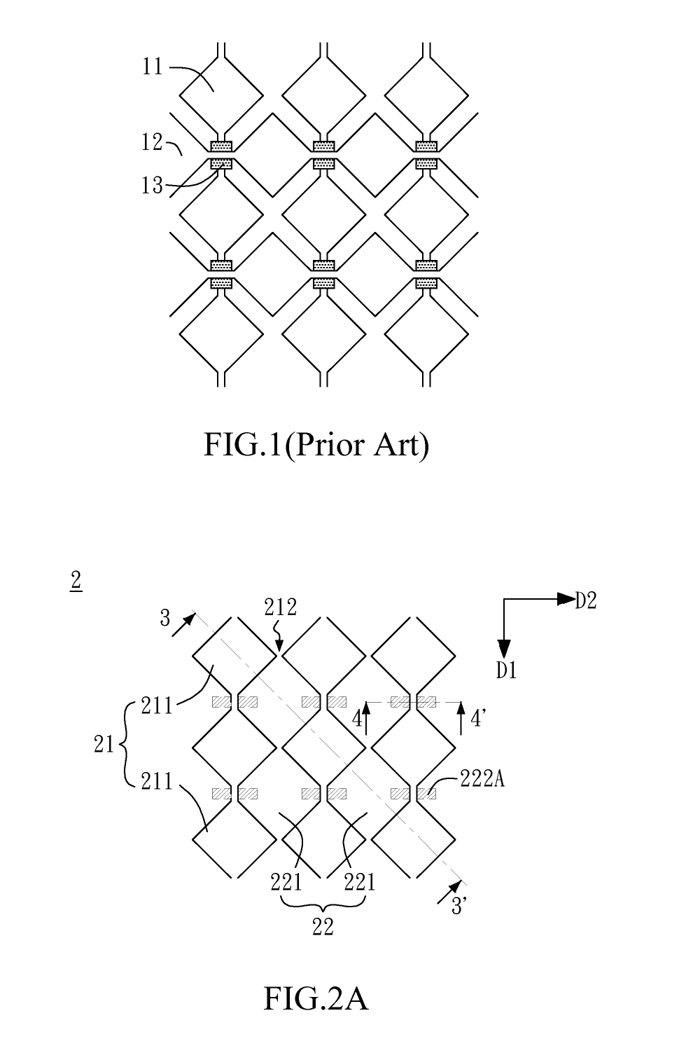

### DETAILED DESCRIPTION OF THE INVENTION

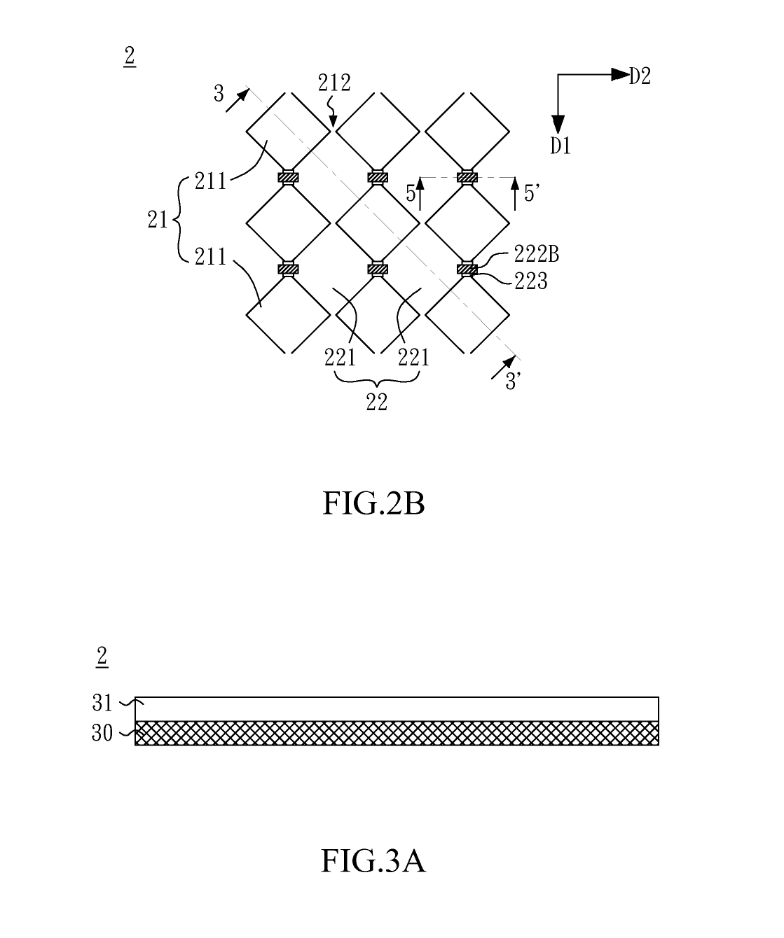

FIG. 2A shows a top view of a touch electrode device 2 according to one embodiment of the present invention. Specifically, the touch electrode device 2 includes plural first electrode lines 21 that are parallel along a first direction D 1, and each first electrode line 21 is composed of serial-connected first electrodes 211. In the embodiment, the first electrodes 211 of the same first electrode line 21 are physically and electrically connected. The touch electrode device 2 also includes plural second electrode lines 22 that are parallel along a second direction D2, and each second electrode line 22 is composed of serial-connected second electrodes 221. In the embodiment, the second electrodes 221 of the same second electrode line 22 are not physically connected, but electrically connected via conductive elements 222A that are respectively disposed between the adjacent second electrodes 221 of the same second electrode line 22. It is noted that the conductive elements 222A are disposed below the second electrodes 221. Moreover, there is a proper space 212 between the adjacent first electrodes 211 along the second direction D2 and there is a proper space 212 between the adjacent second electrodes 221 along the first direction D1, such that the adjacent first electrode lines 21 are electrically insulated from each other and the adjacent second electrode lines 22 are electrically insulated from each other. The space 212 may be obtained in a back-end process by laser technology. In a preferred embodiment, the space 212 has a width of 20-50 micrometers. The first direction D1 and the second direction D2, for example, X and Y, may be substantially orthogonal to each other. However, in another embodiment, the first direction D1 and the second direction D2 may have another specific angle of intersection. Although the first electrodes 211 and the second electrodes 221 of the embodiment are exemplified by rhombus shapes, they may have other shapes instead. The first electrodes 211 and the second electrodes 221 may be composed of transparent material such as indium tin oxide (ITO).

FIG. 2B shows a top view of a touch electrode device 2 according to another embodiment of the present invention. In the embodiment, the second electrodes 221 of the same second electrode line 22 are electrically connected via plural conductive elements 222B, which are disposed above the second electrodes 221. It is noted that the first electrodes 211 and the second electrodes 221 are electrically insulated from each other by insulation bridges 223. Moreover, there is a proper space 212 between the adjacent first electrodes 211 along the second direction D2 and there is a proper space 212 between the adjacent second electrodes 221 along the first direction D1, such that the adjacent first electrode lines 21 are electrically insulated from each other and the adjacent second electrode lines 22 are electrically insulated from each other. The space 212 may be obtained in a back-end process by laser technology. In a preferred embodiment, the space 212 has a width of 20-50 micrometers. The first direction D1 and the second direction D2, for example, X and Y, may be substantially orthogonal to each other. However, in another embodiment, the first direction D1 and the second direction D2 may have another specific angle of intersection. Although the first electrodes 211 and the second electrodes 221 of the embodiment are exemplified by rhombus shapes, they may have other shapes instead. The first electrodes 211 and the second electrodes 221 may be composed of transparent material such as indium tin oxide (ITO).

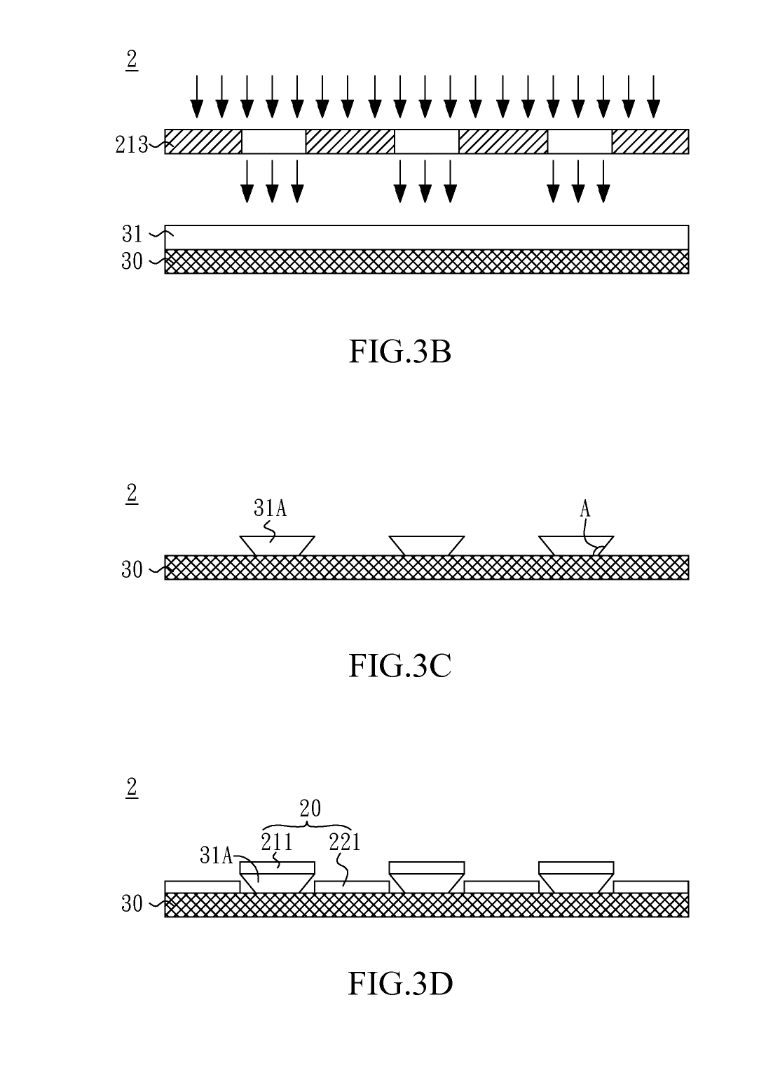

FIG. 3A to FIG. 3D show cross-sectional views illustrating a method of manufacturing the touch electrode device 2 of FIG. 2A/B. Also referring to FIG. 2A, plural conductive elements 222A are first formed on a substrate 30, and formed between the adjacent second electrodes 221 of the same second electrode line 22 (that will be formed afterwards). In another embodiment, also referring to FIG. 2B, the conductive elements 222B are formed in a back-end process after the second electrodes 221 have been formed. The substrate 30 mentioned above may, but not necessarily, be composed of glass.

Subsequently, as shown in FIG. 3A, an insulation layer 31 is formed on the substrate 30. In the embodiment, the insulation layer includes photoresist material or other insulation material. Generally speaking, the insulation layer 31 of the embodiment may be composed of transparent material, which has a refractive index being substantially equal to a refractive index of the first electrodes 211.

As shown in FIG. 3B, the insulation layer 31 is subjected to photolithographic process by a photomask with a pattern of the first electrode line 21, therefore forming a patterned insulation layer 31 as shown in FIG. 3C. FIG. 3C and FIG. 3D show cross-sectional views along a section line 3-3′ in FIG. 2A/B. If photoresist material is used in the insulation layer 31, the patterned insulation layer 31 may be further subjected to baking process, for example, at 280° C. for about 20 minutes.

According to one aspect of the embodiment, as shown in FIG. 3C, the patterned insulation layer 31 includes plural insulation bases 31A, each having an undercut profile such that a top area of the insulation base 31A is greater than a bottom area of the insulation base 31A. In a preferred embodiment, the insulation base 31A has an undercut angle A being greater than 95°.

Afterwards, as shown in FIG. 3D, a transparent electrode layer 20 is formed on both the substrate 30 and the insulation bases 31A overall, for example, by a sputter process, therefore forming the first electrodes 211 on the insulation bases 31A and forming the second electrodes 221 on the substrate 30 at the same time. According to another aspect of the embodiment, an edge of the first electrode 211 is substantially aligned with an edge of the adjacent second electrode 221. As no gap exists between the first electrode 211 and the adjacent second electrode 221, no visual trace occurs when users look at the touch electrode device 2.

In a preferred embodiment, as shown in FIG. 3D, there is a proper height being greater than, for example, 20 micrometers, between a top of the insulation base 31A and a top surface of the second electrode 221, and there is a proper undercut angle A (e.g., greater than 95)°. Accordingly, no unwanted electrical shorting occurs between the first electrode 211 and the second electrode 221.

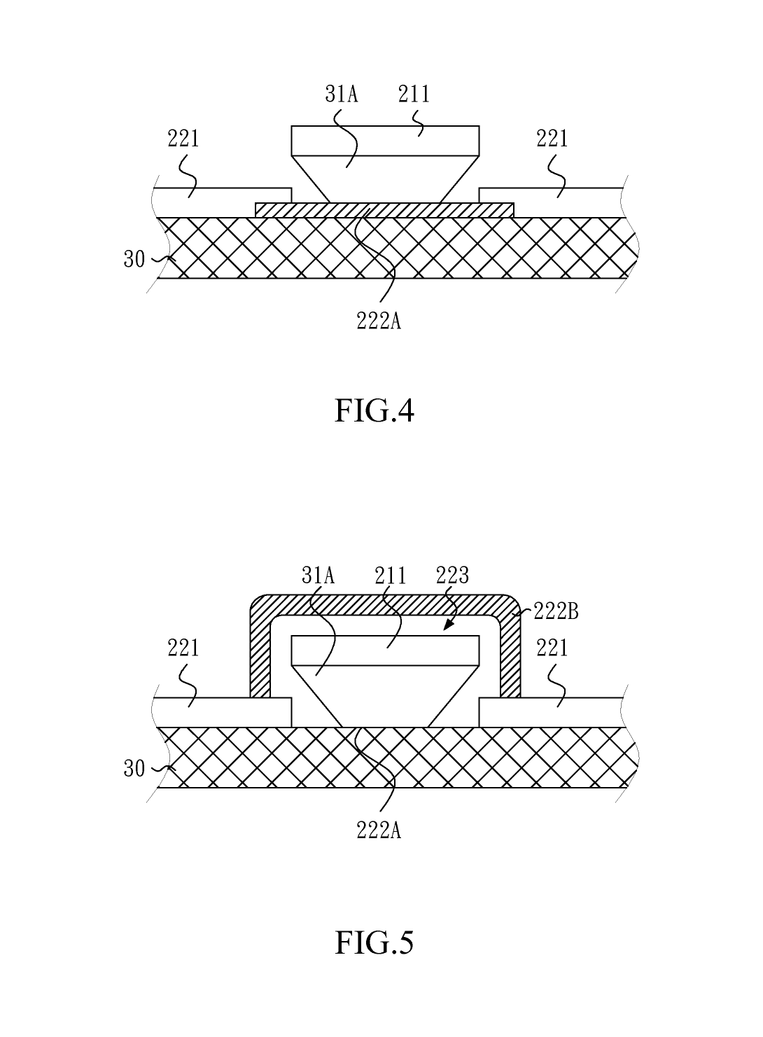

FIG. 4 shows a cross-sectional view along a section line 4-4′ in FIG. 2A. Specifically, the conductive element 222A is used to electrically connect two adjacent second electrodes 221 of the same second electrode line 22. FIG. 5 shows a cross-sectional view along a section line 5-5′ in FIG. 2B. Specifically, the conductive element 222B is used to electrically connect two adjacent second electrodes 221 of the same second electrode line 22, and the insulation bridge 223 is used to electrically insulate the second electrode 221 from the first electrode 211.

Although specific embodiments have been illustrated and described, it will be appreciated by those skilled in the art that various modifications may be made without departing from the scope of the present invention, which is intended to be limited solely by the appended claims.

What is claimed is:

1. A touch electrode device, comprising:
a substrate;
a plurality of insulation bases disposed on the substrate, each said insulation base having an undercut profile such that a top area of the insulation base is greater than a bottom area of the insulation base;
a plurality of first electrode lines disposed on the insulation bases respectively; and
a plurality of second electrode lines disposed on the substrate.

2. The device of claim 1, wherein the first electrode lines and the second electrode lines comprise indium tin oxide (ITO).

3. The device of claim 1, wherein the first electrode lines are disposed along a first direction and each said first electrode line includes a plurality of first electrodes that are physically serial-connected; and the second electrode lines are disposed along a second direction and each said second electrode line includes a plurality of second electrodes.

4. The device of claim 3, further comprising a plurality of conductive elements disposed between the substrate and the second electrode line for electrically connecting the second electrodes of each said second electrode line.

5. The device of claim 3, further comprising a plurality of conductive elements disposed above the second electrode lines for electrically connecting the second electrodes of each said second electrode line, and a plurality of insulation bridges corresponding to the conductive elements for electrically insulating the first electrode lines from the second electrode lines.

6. The device of claim 3, wherein there is a space of about 20-50 micrometers between the adjacent first electrodes along the second direction and there is a space of about 20-50 micrometers between the adjacent second electrodes along the first direction.

7. The device of claim 1, wherein the insulation bases comprise photoresist material.

8. The device of claim 1, wherein the insulation bases have a refractive index being approximately equal to a refractive index of the first electrodes.

9. The device of claim 1, wherein the insulation bases have an undercut angle being greater than 95°.

10. The device of claim 1, wherein there is a height being greater than 20 micrometers between a top of the insulation base and a top surface of the second electrode.

11. A method of manufacturing a touch electrode device that includes a plurality of first electrode lines and a plurality of second electrode lines, the method comprising:
forming an insulation layer on a substrate;
patterning the insulation layer with a pattern of the first electrode lines to form a plurality of insulation bases, each said insulation base having an undercut profile such that a top area of the insulation base is greater than a bottom area of the insulation base; and
forming an electrode layer on the substrate and the insulation bases, thereby resulting in the first electrode lines disposed on the insulation bases and the second electrode lines disposed on the substrate.

12. The method of claim 11, wherein the first electrode lines and the second electrode lines comprise indium tin oxide (ITO).

13. The method of claim 11, wherein the first electrode lines are disposed along a first direction and each said first electrode line includes a plurality of first electrodes that are physically serial-connected; and the second electrode lines are disposed along a second direction and each said second electrode line includes a plurality of second electrodes.

14. The method of claim 13, before forming the insulation layer, further comprising a step of forming a plurality of conductive elements on the substrate to electrically connect the second electrodes of each said second electrode line.

15. The method of claim 13, after forming the electrode layer, further comprising a step of sequentially forming a plurality of insulation bridges and a plurality of conductive elements, wherein the conductive elements are disposed above the second electrode lines for electrically connecting the second electrodes of each said second electrode line, and the insulation bridges are corresponding to the conductive elements for electrically insulating the first electrode lines from the second electrode lines.

16. The method of claim 15, wherein a space of about 20-50 micrometers between the adjacent first electrodes along the second direction is made by laser, and a space of about 20-50 micrometers between the adjacent second electrodes along the first direction is made by laser.

17. The method of claim 11, wherein the insulation layer comprises photoresist material.

18. The method of claim 11, wherein the insulation bases have a refractive index being approximately equal to a refractive index of the first electrodes.

19. The method of claim 11, wherein the insulation bases have an undercut angle being greater than 95°.

20. The method of claim 11, wherein the electrode layer is formed by sputter process.
